(19) United States
(12) Patent Application Publication
(10) Pub. No.: US 2013/0127037 A1
(43) Pub. Date: May 23, 2013

(54) SEMICONDUCTOR DEVICE BUILT-IN SUBSTRATE

(71) Applicants: Kentaro Mori, Tokyo (JP); Shintaro Yamamichi, Tokyo (JP); Katsumi Kikuchi, Tokyo (JP); Daisuke Ohshima, Tokyo (JP); Yoshiki Nakashima, Tokyo (JP); Hideya Murai, Tokyo (JP)

(72) Inventors: Kentaro Mori, Tokyo (JP); Shintaro Yamamichi, Tokyo (JP); Katsumi Kikuchi, Tokyo (JP); Daisuke Ohshima, Tokyo (JP); Yoshiki Nakashima, Tokyo (JP); Hideya Murai, Tokyo (JP)

(73) Assignee: NEC CORPORATION, Minato-ku, Tokyo (JP)

(21) Appl. No.: 13/638,421

(22) PCT Filed: Mar. 3, 2011
(86) PCT No.: PCT/JP2011/054881

§ 371 Date: Dec. 21, 2012

(30) Foreign Application Priority Data
Mar. 31, 2010 (JP) 2010-081443

(51) Int. Cl. H01L 23/34

(52) U.S. Cl. CPC H01L 23/34
USPC 257/712; 257/773

(57) ABSTRACT

An object of the present invention is to provide a semiconductor device built-in substrate, which can be made thin and can suppress occurrence of warpage. The present invention provides a semiconductor substrate which is featured by including a first semiconductor device serving as a substrate, a second semiconductor device placed on the circuit surface side of the first semiconductor device in the state where the circuit surfaces of the first and second semiconductor devices are placed to face in the same direction, and an insulating layer incorporating therein the second semiconductor device, and which is featured in that a heat dissipation layer is formed at least between the first semiconductor device and the second semiconductor device, and in that the heat dissipation layer is formed on the first semiconductor device so as to extend up to the outside of the second semiconductor device.

### TECHNICAL FIELD

The present invention relates to a semiconductor device built-in substrate.

### BACKGROUND ART

For the purpose of achieving higher integration and higher performance of an electronic device, such as a semiconductor device, there has been proposed a packaging technique, so-called a semiconductor built-in technique, for embedding a semiconductor device. In a semiconductor device built-in substrate, a semiconductor device is embedded in the substrate, and thereby the mounting area of the semiconductor device can be suppressed. The semiconductor built-in technique is expected as a high-density mounting technique which achieves higher integration and higher performance of a semiconductor device and which achieves thickness reduction, cost reduction, high-frequency measures, low stress connections, and the like, in a package.

However, in a semiconductor device built-in substrate, since an insulating layer is formed so as to cover the semiconductor device, there is a case where most of the heat generated by the semiconductor device is accumulated in or in the vicinity of the semiconductor device, thereby resulting in an increase of the temperature of the semiconductor device.

To cope with this, Patent Literature 1 discloses a semiconductor device built-in substrate (see FIG. 17), in which, in the state where the circuit surface of semiconductor device 1002 is held on the upper side, semiconductor device 1002 is placed, via adhesive layer 1003, on metal plate 1001 serving as a supporting body, and is then embedded in insulating layer 1004, and in which wiring layer 1005 is laminated on the insulating layer. In Patent Literature 1, metal plate 1001 is used as a supporting body of semiconductor device 1002, and thereby it is possible to provide a semiconductor device built-in substrate, which can suppress the warpage of the semiconductor device, and which has excellent heat dissipation characteristics.

Further, Patent Literature 2 discloses a semiconductor device built-in substrate, in which a semiconductor device is placed on a substrate made of silicon having excellent thermal conductivity, and in which an insulating layer is formed on the silicon substrate so as to cover the semiconductor device. By using the thermal conductivity of the silicon substrate, it is possible to manufacture a low thermal resistance type semiconductor device built-in substrate.

Further, Patent Literature 2 describes that an electronic circuit including an active element, and the like, may be formed in the silicon substrate itself.

### CITATION LIST

### Patent Literature

Patent Literature 1: JP2001-15650A
Patent Literature 2: JP2007-318059A

### SUMMARY OF INVENTION

### Technical Problem

As suggested in Patent Literature 2, it is possible to achieve higher integration and higher performance of a semiconductor device built-in substrate by using a semiconductor device as a substrate serving as a supporting body. However, in the state where a second semiconductor device is placed on the circuit surface side of a first semiconductor device serving as a substrate, when the semiconductor devices are operated, the electronic circuit of the first semiconductor device receives heat from the second semiconductor device. Especially, the electronic circuit portion of the first semiconductor device, which portion is located on the back surface of the second semiconductor device, receives more heat from the second semiconductor device. Therefore, in the case where the electronic circuit of the first semiconductor device is weak against heat, an operation failure may be caused due to the heat.

An object of the present invention is to provide a semiconductor device built-in substrate, in which a semiconductor device is used as the substrate, and which has excellent heat dissipation characteristics.

### Solution to Problem

Therefore, the present invention is to provide a semiconductor device built-in substrate comprising:

a first semiconductor device serving as a substrate,

a second semiconductor device placed on a circuit surface side of the first semiconductor device in a state where the circuit surfaces of the first and second semiconductor devices are placed to face the same direction, and

an insulating layer in which the second semiconductor device is embedded, and

wherein a heat dissipation layer is formed at least between the first semiconductor device and the second semiconductor device, and

in that the heat dissipation layer is formed on the first semiconductor device so as to extend to the outside of the second semiconductor device.

### Advantageous Effects of Invention

In the present invention, the heat dissipation layer is formed between the first semiconductor device serving as a substrate and the embedded second semiconductor device, and thereby can improve the heat dissipation characteristics and can suppress an operation failure due to the heat.

### BRIEF DESCRIPTION OF DRAWINGS

FIG. 1 is a schematic sectional view showing a configuration example of a semiconductor device built-in substrate according to an exemplary embodiment, and showing a state where a heat dissipation layer is extended on a first semiconductor device.

FIG. 2 is a schematic top view showing a state where a heat dissipation layer is formed on the inner side of a plurality of first electrode terminals arranged in a peripheral form.

FIG. 3 is a schematic sectional view showing a configuration example of a semiconductor device built-in substrate according to an exemplary embodiment, and showing a state where a heat dissipation layer is formed to be extended on a first semiconductor device so as to be exposed on the side surface of the substrate with the built-in semiconductor device.

FIG. 4 is a schematic top view showing a state where a heat dissipation layer is formed to be exposed on the side surface of a semiconductor device built-in substrate.

FIG. 5(a) is a schematic top view showing a state where a heat dissipation layer is formed not to contact first electrode terminals.

FIG. 5(b) is a schematic top view showing a state where a heat dissipation layer is formed to contact first electrode terminals.

FIG. 6 is a schematic sectional view showing a configuration example of a semiconductor device built-in substrate according to an exemplary embodiment, and showing a state where a heat dissipation layer is formed in an area in which a second semiconductor device is placed, and where a heat dissipation layer is formed between respective function blocks.

FIG. 7(a) is a schematic top view showing an example of arrangement of function blocks in a first semiconductor device.

FIG. 7(b) is a schematic top view showing a state where a heat dissipation layer is formed in an area in which a second semiconductor device is placed, and where a heat dissipation layer is formed between respective function blocks.

FIG. 8(a) is a schematic top view showing an example of arrangement of function blocks in a first semiconductor device.

FIG. 8(b) is a schematic top view showing a state where a heat dissipation layer is formed in an area in which a second semiconductor device is placed, and where a heat dissipation layer is formed in an area not facing the respective function blocks.

FIG. 9 is a schematic sectional view showing a configuration example of a semiconductor device built-in substrate according to an exemplary embodiment, and showing a state where heat dissipation vias are formed so as to be in contact with a heat dissipation layer.

FIG. 10 is a horizontal sectional view taken along the dotted line Y of FIG. 9, and is a schematic sectional view showing a state where the heat dissipation vias are formed on the heat dissipation layer.

FIG. 11 is a schematic sectional view showing a configuration example of a semiconductor device built-in substrate according to an exemplary embodiment, and showing a state where heat dissipation passage are formed in an adhesive layer.

FIG. 12 is a schematic top view showing an example of arrangement of the heat dissipation passages formed in the adhesive layer.

FIG. 13 is a schematic sectional view showing a configuration example of a semiconductor device built-in substrate according to an exemplary embodiment, and showing a state where second heat dissipation paths are provided in a second semiconductor device.

FIG. 14 is a schematic sectional view showing a configuration example of a semiconductor device built-in substrate according to an exemplary embodiment, and showing a state where the second heat dissipation paths and the heat dissipation passages are formed to be in contact with each other.

FIG. 15(a) is a schematic sectional view showing a configuration example of a semiconductor device built-in substrate according to an exemplary embodiment, and showing a state where first heat dissipation paths are provided in a first semiconductor device.

FIG. 15(b) is a schematic sectional view showing a state where the first heat dissipation paths penetrate the first semiconductor device so as to be in contact with the heat dissipation layer.

FIG. 16 is a cross-sectional process diagram showing an example of a manufacturing method of a semiconductor device built-in substrate according to exemplary embodiment 1.

FIG. 17 is a schematic sectional view for explaining a configuration of a conventional semiconductor device built-in substrate.

### DESCRIPTION OF EMBODIMENTS

In the present invention, a first semiconductor device is used as a substrate. A second semiconductor device is placed on the first semiconductor device used as the substrate, and the second semiconductor device is embedded in an insulating layer. Further, the circuit surface of the first semiconductor device and the circuit surface of the second semiconductor device are placed to face in the same direction. That is, the second semiconductor device with its circuit surface facing upward is placed on the first semiconductor device with its circuit surface facing upward. Further, a heat dissipation layer is formed between the first semiconductor device and the second semiconductor device and is placed on the first semiconductor device so as to extend to the outside of the second semiconductor device.

In the present invention, it is possible to achieve higher integration and higher performance of a semiconductor device built-in substrate by using a semiconductor device as a substrate serving as a supporting body. Further, heat accumulated between the first semiconductor device and the second semiconductor device can be effectively diffused to the other area in such a manner that the heat dissipation layer is formed between the first semiconductor device and the second semiconductor device, and that the heat dissipation layer is formed on the first semiconductor device so as to extend to the outside of the second semiconductor device. Therefore, the present invention can provide a semiconductor device built-in substrate which has excellent heat dissipation characteristics and which can achieve higher integration and higher performance.

In the following, exemplary embodiments will be described with reference to the accompanying drawings. Note that the present invention is not limited to the exemplary embodiments described below.

### Exemplary Embodiment 1

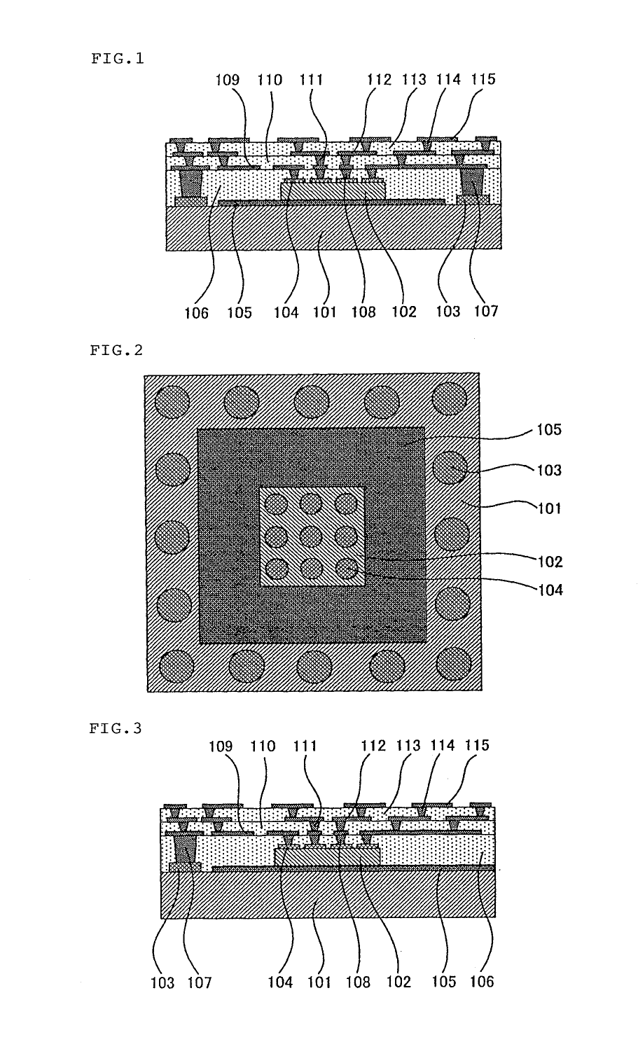

FIG. 1 is a schematic sectional view for explaining a semiconductor device built-in substrate of an exemplary embodiment.

In FIG. 1, heat dissipation layer 105 is formed on first semiconductor device 101 serving as a substrate, and second semiconductor device 102 is placed on heat dissipation layer 105. In FIG. 1, the circuit surfaces of first semiconductor device 101 and of second semiconductor device 102 are both placed so as to face upward and to be directed in the same direction. Further, first semiconductor device 101 and second semiconductor device 102 have first electrode terminal 103 and second electrode terminal 104 on the circuit surface side, respectively. Heat dissipation layer 105 is formed between first semiconductor device 101 serving as the substrate and second semiconductor device 102. Further, an adhesive (not shown) may also be formed between heat dissipation layer 105 and the second semiconductor device.

Further, insulating layer 106 is arranged on first semiconductor device 101 and heat dissipation layer 105 so as to incorporate therein second semiconductor device 102. First wiring layer 109 is arranged on insulating layer 106. At least one wiring of first wiring layer 109 is electrically connected to second electrode terminal 104 via device connected via 108 formed in insulating layer 106. Further, at least one wiring of first wiring layer 109 is electrically connected to first electrode terminal 103 via wiring connected via 107 formed in insulating layer 106.

First wiring layer 109 is covered with first wiring insulating layer 110, and second wiring layer 112 is arranged on first wiring insulating layer 110. At least one wiring of second wiring layer 112 is electrically connected to at least one wiring of first wiring layer 109 via first via 111 formed in first wiring insulating layer 110. Second wiring layer 112 is covered with second wiring insulating layer 113, and third wiring layer 115 is arranged on second wiring insulating layer 113. At least one wiring of third wiring layer 115 is electrically connected to at least one wiring of second wiring layer 112 via second via 114 formed in second wiring insulating layer 113. The wiring layer includes wirings such as, for example, a signal wiring, a power supply wiring, and a ground wiring.

Further, although not illustrated, one or more wiring layers can be further provided on the side opposite to the substrate, that is, on the wiring layer side. Further, an external connection terminal used for connection with an external substrate and the like, can be provided on the outermost layer. As the external connection terminal, for example, a BGA ball is arranged so as to be connected to an external substrate, such as a mother board. Further, the external connection terminal may have a configuration in which a wiring layer is exposed at an opening of a solder resist. Further, the surface of the external connection terminal can be protected so as to prevent, for example, a flow of a solder.

Further, in FIG. 1, first wiring layer 109 is electrically connected to second electrode terminal 104 by using device connected via 108, but the connection is not limited in particular to this. A metallic post provided on the electrode terminal can also be used instead of the device connected via. Further, a metallic post provided on the electrode terminal can also be used instead of wiring connected via 103.

Here, FIG. 2 is a schematic top view showing a state where, in the semiconductor device built-in substrate shown in FIG. 1, heat dissipation layer 105 is formed on first semiconductor device 101 serving as the substrate, and second semiconductor device 102 is placed on heat dissipation layer 105. In FIG. 2, the first semiconductor device is a peripheral type in which electrode terminals are provided on the outer peripheral surface of the first semiconductor device. Heat dissipation layer 105 is formed to cover at least the whole surface (back surface) of the second semiconductor device, the surface being opposite to the circuit surface of the second semiconductor device. Further, heat dissipation layer 105 is formed on the first semiconductor device so as to extend to the outside of the second semiconductor device. Further, heat dissipation layer 105 is formed on the inner side of a plurality of first electrode terminals 103. Heat dissipation layer 105 is formed between first semiconductor device 101 and second semiconductor device 102 and formed to extend to the outside of second semiconductor device 102 along the surface direction, thereby the heat accumulated between first semiconductor device 101 and second semiconductor device 102 can be dissipated to the other area.

The heat dissipation material used for the heat dissipation layer is not limited in particular, and any material having thermal conductivity higher than that of the semiconductor devices can be used. Examples of the semiconductor material which can be used for the heat dissipation layer include silicon (Si), germanium (Ge), gallium arsenide (GaAs), gallium arsenide phosphide (GaAsP), gallium nitride (GaN), silicon carbide (SiC), zinc oxide (ZnO). Among these materials, silicon is most commonly used as the material of the semiconductor material, and in this case, a heat dissipation material having thermal conductivity higher than that of silicon is used. Note that the thermal conductivity of silicon is about 170 W/m·K, and hence a material having thermal conductivity larger than 170 W/m·K can be preferably used as the heat dissipation material. Examples of the heat dissipation material include a metallic material, a carbon material, a resin material, and the like. The metallic material includes metal, metal oxide, metal nitride, metal carbide, and an alloy of these materials. Examples of the metallic material include gold, silver, copper, aluminum, iron, platinum, titanium, aluminum oxide, aluminum nitride, titanium carbide, and the like. Examples of the carbon material include diamond, graphite, carbon nanotube, and the like. Examples of the resin material include silicone-based resin, epoxy-based resin, and the like. Further, a mixture of these materials may also be used. For example, it is possible to use a mixed material of a resin material and a metallic material, such as a metal powder, a metal flake, a metal fiber, or a filler metal.

The method for forming the heat dissipation layer is not limited in particular, and for example, the heat dissipation layer can be formed in such a manner that a heat dissipation material is deposited by using a sputtering method, a vacuum vapor deposition method, a plating method, or the like, and then the deposited material is formed into a predetermined shape by a photolithography method.

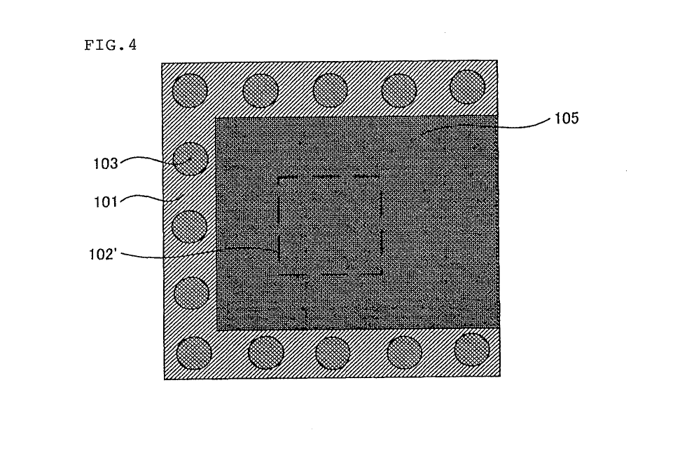

As described above, the heat dissipation layer is formed between the first semiconductor device and the second semiconductor device, and is formed on the first semiconductor device so as to extend to the outside of the second semiconductor device. Further, it is preferred that the heat dissipation layer is formed to cover at least the whole back surface of the second semiconductor device. Further, as shown in FIG. 3 and FIG. 4, the heat dissipation layer can also be formed so as to be partially exposed to the outer part. When a part of the heat dissipation layer is exposed to the outside, heat can be efficiently dissipated to the outside. In FIG. 3 and FIG. 4, dotted line 102′ shows the arranged position of the second semiconductor device. Note that the position of the electrode terminals of the first semiconductor device can be arbitrarily changed by a rewiring layer.

Further, it is preferred that the heat dissipation layer is formed not to contact the first electrode terminal and the wiring connected via. When the heat dissipation layer is formed of an insulating material, the heat dissipation layer may be in contact with the first electrode terminal. Examples of the insulating material, which can be used for the heat dissipation layer, include aluminum nitride, titanium carbide, aluminum oxide, and the like. In the case where the heat dissipation layer is formed by using an insulating material, no problem is caused even when the heat dissipation layer is formed to contact the first electrode terminal or the wiring connected via. The heat dissipation layer formed of the insulating material is desirable because the tolerance to design errors is improved.

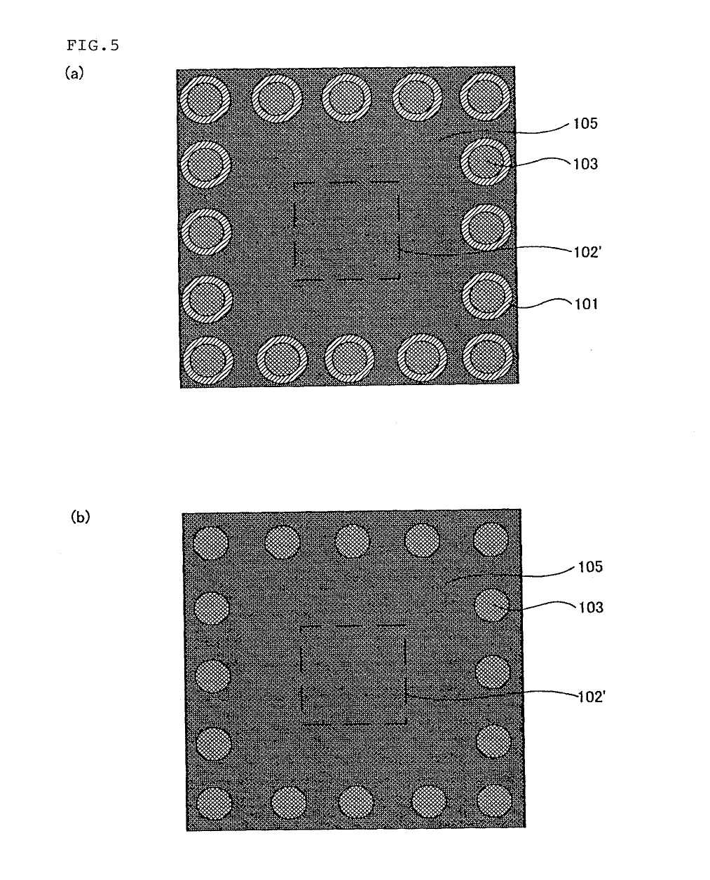

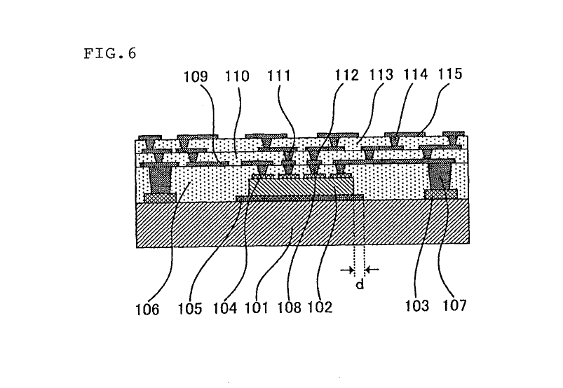

For example, as shown in FIG. 5(a), it is preferred that first electrode terminal 103 and heat dissipation layer 105 are formed not to contact each other. In FIG. 5(a), the heat dissipation layer is formed to cover the whole surface of the first semiconductor device so as not to contact the first electrode terminals, and the end portion of the heat dissipation layer is exposed on the side surface of the built-in substrate. With such configuration, the heat accumulated between the first semiconductor device and the second semiconductor device is more effectively diffused to the other area, so as to be dissipated to the outside. Further, as described above, when the insulating property of the heat dissipation layer is ensured, the first electrode terminal and the heat dissipation layer may be formed to contact each other as shown in FIG. 5(b).

Examples of the semiconductor device include a transistor, an IC, an LSI, and the like. For example, a CMOS (Complementary Metal Oxide Semiconductor) can be selected as a basic circuit of an LSI.

In order to arrange second semiconductor device 102 at the center of first semiconductor device 101, it is preferred to use a peripheral-type first semiconductor device 101 in which electrode terminals are provided on the surface of the outer side of first semiconductor device 101. However, the present invention is not limited in particular to this. For example, FIG. 2 shows peripheral-type first semiconductor device 101 in which the electrode terminals are provided on the surface of the outer side of first semiconductor device 101. However, the present invention is not limited in particular to this, and it is only necessary that first electrode terminals 103 are arranged in portions other than the area in which second semiconductor device is placed. Further, the first semiconductor device can include a rewiring layer on the side of the circuit surface. For example, when it is not possible to secure the area in which the second semiconductor device of a full grid type is placed, the positions of electrode terminals can be changed by using a rewiring layer. The methods for forming the rewiring layer are disclosed, for example, in JP2006-32600A and JP2009-194022A. For example, the rewiring layer can be formed by a plurality of layers on the circuit surface of a semiconductor device by using a photolithography method.

First semiconductor device 101 also functions as a substrate. Conventionally, a metal plate, such as a copper plate, is used as a semiconductor device built-in substrate. However, in the present invention, it is possible to achieve higher integration and higher performance by using a functional semiconductor device as a substrate. The thickness of the first semiconductor device can be set, for example, to 50 to 1000 μm, and is preferably set to 200 to 500 μm.

The thickness of the second semiconductor device can be set, for example, to 50 to 500 μm, and is preferably set to 50 to 100 μm.

Further, in the present invention, it is preferred that the first semiconductor device is configured by a memory and that the second semiconductor device is configured by a logic circuit. This is because, in the configuration of the present invention, it is preferred that the first semiconductor device placed on the lower side is configured by a memory having a relatively large pad pitch and a relatively small number of pads, and that the second semiconductor device placed on the upper side is configured by a logic circuit having a relatively small pad pitch and a relatively large number of pads. Further, in particular, since the amount of heat generated by the logic circuit is large and the memory tends to be weak against heat, when the first semiconductor device is configured by a memory and when the second semiconductor device is configured by a logic circuit, the heat generated by the logic circuit is accumulated between the semiconductor devices, thereby may easily cause damage to the memory element placed at the heat accumulated portion. Then, as in the present invention, the heat can be effectively dissipated to the other area by arranging the heat dissipation layer between the first semiconductor device configured by a memory element and the second semiconductor device configured by a logic circuit, and thereby the destruction of the memory element can be prevented.

Further, as described above, an adhesive layer may be provided between second semiconductor device 102 and heat dissipation layer 105. The adhesive used for the adhesive layer is not limited in particular, and for example, epoxy resin, epoxyacrylate resin, urethane acrylate resin, polyester resin, phenol resin, polyimide resin, and the like, can be used. Further, it is preferred to use an adhesive having good thermal conductivity, and for example, silver paste can be used. Further, from the viewpoint of thermal conductivity, it is preferred that the thickness of the adhesive layer be as thin as possible.

The material of the insulating layer is not limited in particular, and any material having an insulating property can be used. For example, an insulator used for a common wiring substrate can be used. Examples of the material of the insulating layer include epoxy resin, epoxyacrylate resin, urethane acrylate resin, polyester resin, phenol resin, polyimide resin, poly norbornene resin, and the like. In addition, examples of the material of the insulating layer include BCB (Benzocyclobutene), PBO (Polybenzoxazole), and the like. Among these materials, polyimide resin and PBO have excellent mechanical properties, such as a film strength, a tensile elastic modulus, a breaking elongation rate, and hence can provide high reliability. The material of the insulating layer may be any of a photosensitive material or a non-photosensitive material. The insulating layer may be formed of a plurality of layers, but in this case, it is preferred to use the same material for each of the plurality of layers.

As described above, insulating layer 106 may be configured by a plurality of layers, and for example, may be configured by a core layer having an opening portion for arranging therein the second semiconductor device, and a filling resin filled in the opening portion in which the second semiconductor device is placed.

The same material as that used for the insulating layer described above can be used as the material of the wiring insulating layer.

The material of the conductor used for the wiring layer and the vias (including the wiring connected via, the device connected via, the first via, and the like) is not limited in particular, and for example, a metal including at least one selected from a group consisting of copper, silver, gold, nickel, aluminum, and palladium, or an alloy mainly including the material of the group can be used as the material of the conductor. Among these materials, Cu is preferably used for the conductor from the viewpoint of an electric resistance value and cost.

Further, the material of the via is not limited in particular as long as it has a conductive property. Other than the above-described materials, for example, a soldering material, and a conductive resin paste containing thermosetting resin and conductive metal powder of copper, silver, or the like, can be used as the material of the via. It is preferred that a paste material containing nanoparticles as conductive particles be used as the conductive resin paste. Further, it is preferred to use, as the conductive resin paste, a material containing a volatile resin component, or a material containing a resin component which is sublimated when the material is heated and brought close to a sintered compact. More preferably, the via is provided by a vapor deposition method, a sputtering method, a CVD (Chemical Vapor Deposition) method, an ALD (Atomic Layer Deposition) method, an electroless plating method, an electrolytic plating method, or the like, which can stably provide a via having rigidity. Examples of the manufacturing method of the via include a method in which a feeding layer is provided by the vapor deposition method, the sputtering method, the CVD method, the ALD method, the electroless plating method, or the like, and then a desired film thickness is obtained by the electrolytic plating method or the electroless plating. Further, the opening diameter of the via is preferably set to be equal to about the film thickness of the via, but is not limited in particular. The aspect ratio of the via height to the via diameter is preferably set to 0.3 or more to 3 or less, more preferably set to 0.5 or more to 1.5 or less, and further preferably set to about 1.

One or more second semiconductor devices can be provided on the first semiconductor device. As shown in FIG. 1, it is preferred that one second semiconductor device be provided on the first semiconductor device, but the number of the second semiconductor devices provided on the first semiconductor device is not limited in particular to this.

Further, the external connection terminal can be formed of, for example, at least a material selected from a group consisting of gold, silver, copper, tin, and a solder material, or an alloy of the materials of the group. The external connection terminal can be formed, for example, by laminating a nickel layer having a thickness of 3 μm and a gold layer having a thickness of 0.5 μm in order. The pitch between the external connection terminals is preferably set to 50 to 1000 μm and more preferably set to 50 to 500 μm.

### Exemplary Embodiment 2

The exemplary embodiment describes an embodiment where the heat dissipation layer is formed in a region on the first semiconductor device, in which region the second semiconductor device is placed, and is also placed in a region on the first semiconductor device, which region does not face each function block of the first semiconductor device.

A semiconductor devices, such as an LSI, can be configured by a various function blocks, such as, for example, an interface block, a drive block, an A/D conversion block, a logic circuit block, a CPU block, a memory block, and a compression circuit block.

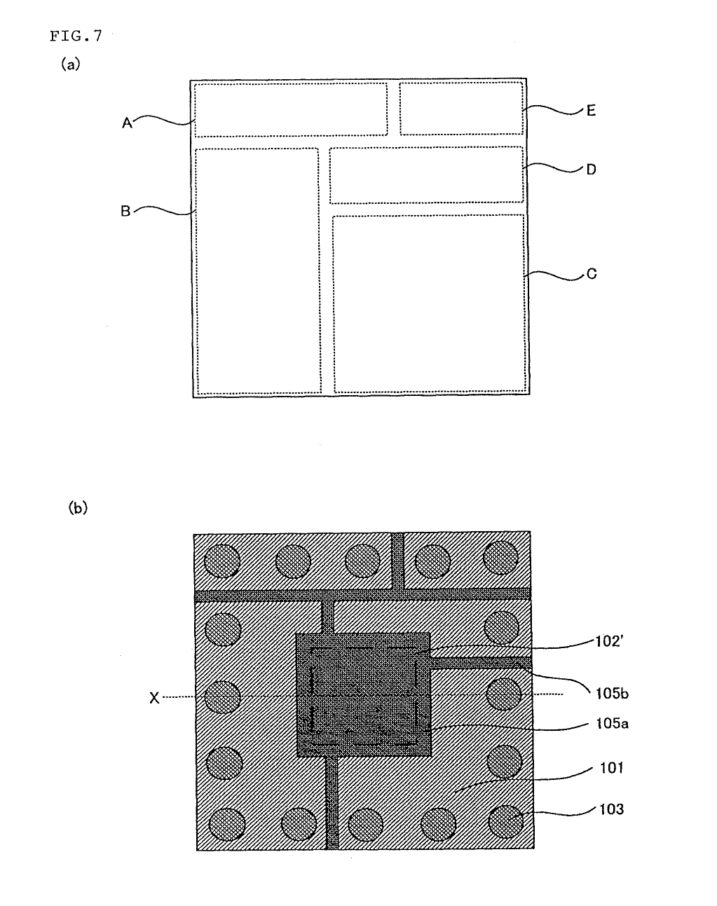

For example, as shown in FIG. 7, a semiconductor device is configured by function blocks A to E respectively shown by the dotted lines. Each of the function blocks can be configured by a basic element. The function blocks are respectively arranged at an arbitrary distance therebetween, and no basic element exists in the region between the function blocks of the semiconductor device. Therefore, when the heat dissipation layer is formed in a region, such as a region between the respective function blocks, which region does not face the function block, it is possible to suppress damage to the basic element.

That is, the heat dissipation layer is formed in the region in which the second semiconductor device is placed, and also in the region which does not face each of the function blocks of the first semiconductor device, thereby can dissipate the heat accumulated between the first semiconductor device and the second semiconductor device to the other region, while suppressing damage to the basic element. Further, in consideration of an arrangement error, the area of the region, in which the second semiconductor device is placed, can be made slightly larger than the back surface side area of the second semiconductor device.

The shape of the heat dissipation layer shown in FIG. 7 is described in more detail as follows. The heat dissipation layer includes heat dissipation plane 115a on which the second semiconductor device is placed, and heat dissipation pathway 115b which is extended from the heat dissipation plane. The heat dissipation pathway is formed between the respective function blocks of the first semiconductor device. Further, the heat dissipation pathway extending from the heat dissipation plane is exposed up to the side surface of the built-in substrate. The shape of the heat dissipation plane, on which the second semiconductor device is placed, is preferably the same as the back surface shape of the second semiconductor device, and the area of the heat dissipation plane is preferably slightly larger than the back surface side area of the second semiconductor device in consideration of an arrangement error. For example, in FIG. 6, which is a vertical sectional view of the substrate with the built-in semiconductor device taken along the dotted line X of FIG. 7(b), the distance d from the end portion of second semiconductor device 102 to the end portion of heat dissipation layer 105 can be set to 50 to 200 μm.

Further, the distance between the respective function blocks is not limited in particular, but the function blocks are arranged to have a distance of, for example, 1 to 10 μm therebetween.

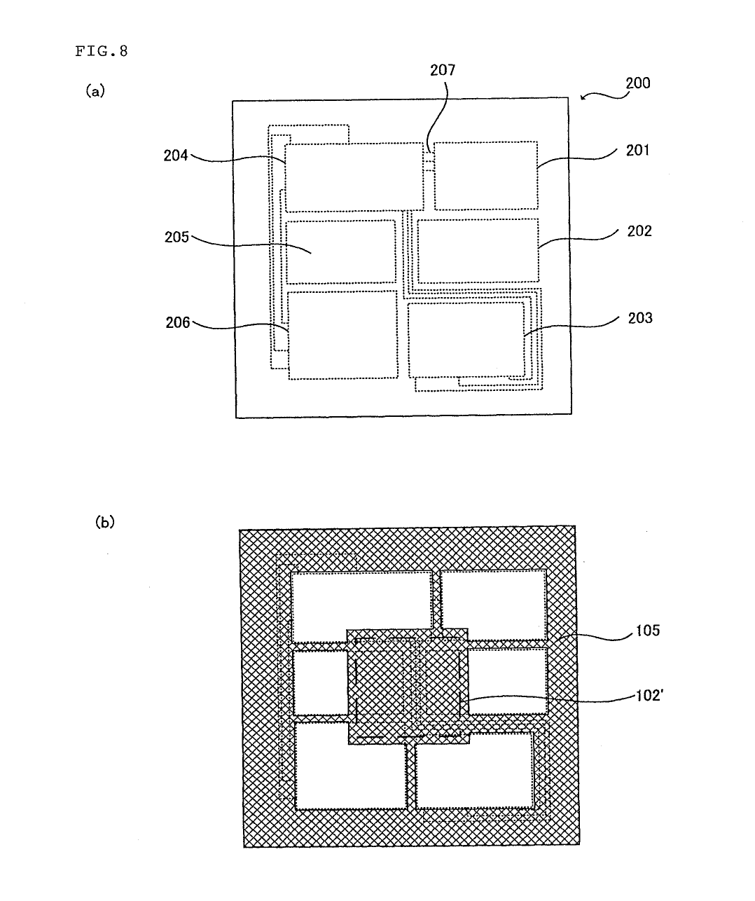

Further, as another example, FIG. 8 shows a specific layout of the function blocks and the heat dissipation layer. In FIG. 8(a), reference numeral 200 denotes a first semiconductor device. Reference numeral 201 denotes a CPU block. Reference numeral 202 denotes a ROM block. Reference numeral 203 denotes a first logic circuit block. Reference numeral 204 denotes a second logic circuit block. Reference numeral 205 denotes a RAM block. Reference numeral 206 denotes a third logic circuit block. Reference numeral 207 denotes a wiring. In FIG. 8(b), reference numeral 102′ denotes an arrangement position of the second semiconductor device which is placed at the center of the first semiconductor device. Heat dissipation layer 105 is formed in the area in which the second semiconductor device is placed, and also in the area which does not face each of the function blocks of the first semiconductor device. Further, the end portion of heat dissipation layer 105 is exposed on the whole side surface of the built-in substrate. With such configuration, it is possible to effectively dissipate the heat accumulated between the first semiconductor device and the second semiconductor device to the outside while suppressing damage to the basic element.

### Exemplary Embodiment 3

The exemplary embodiment describes an embodiment where a heat dissipation via, which is in contact with the first wiring layer and the heat dissipation layer, is formed in the insulating layer.

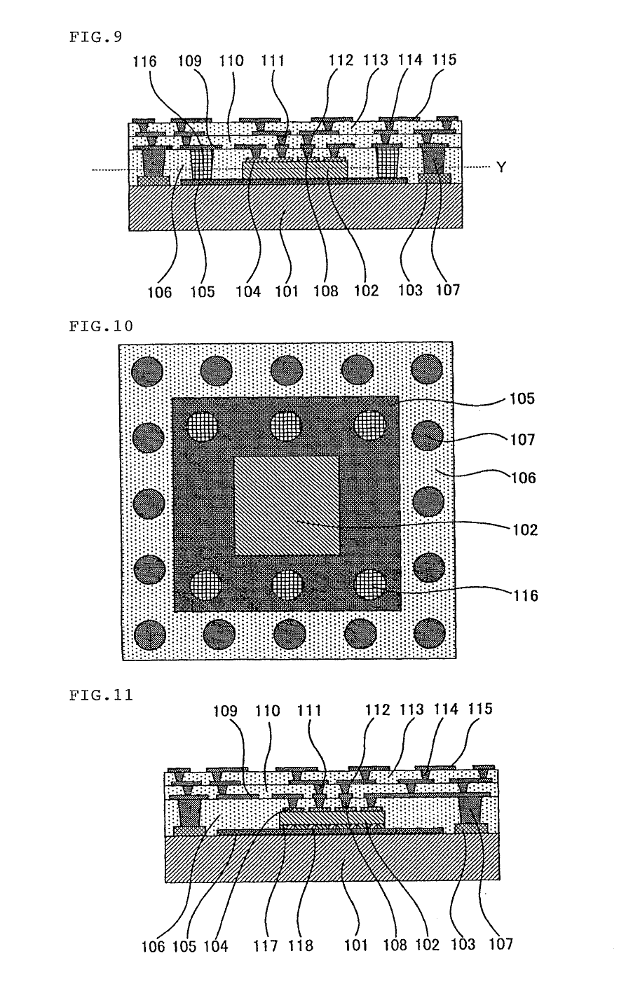

FIG. 9 is a schematic sectional view of the exemplary embodiment. FIG. 10 is a horizontal sectional view taken along the dotted line Y in FIG. 9, and is a view showing an arrangement example of heat dissipation vias in the exemplary embodiment.

As shown in FIG. 9, heat dissipation via 116, the upper and lower surfaces of which are respectively in contact with first wiring layer 109 and heat dissipation layer 105, is formed in insulating layer 106. Heat dissipation via 116 functions as a path through which the heat of heat dissipation layer 105 is dissipated to the front surface side of the built-in substrate. In order to prevent heat conduction to first electrode terminal 103, it is preferred that heat dissipation via 116 is not connected to wiring connected via 107 via a wiring. Specifically, for example, it is preferred that the heat dissipation wiring of the wiring layer, which wiring is connected to heat dissipation via 116, is not electrically connected to the heat dissipation via. Further, similarly, in order to prevent heat conduction to second electrode terminal 104, it is preferred that heat dissipation via 116 be not connected to wiring connected via 107 via a wiring.

The heat dissipation wiring in the wiring layer, which wiring connected to heat dissipation via 116, can be connected to at least one of the external connection terminals on the outermost layer. For example, a BGA ball is arranged at the external connection terminal, and heat can be efficiently dissipated to the mother board via the BGA ball.

As the material of the heat dissipation via, it is possible to use the same material as the above-described heat dissipation material and the above-described conductor material used for the wiring connected via. When heat dissipation via 1 is formed by using the same material as the conductor material used for the wiring connected via, the heat dissipation via can be formed by the plating method simultaneously with the wiring connected via. In this case, heat dissipation via 1 is formed in a configuration referred to as a filled via in which the opening portion is filled with a metallic conductor.

### Exemplary Embodiment 4

The exemplary embodiment describes an embodiment where a heat dissipation passage is formed in an adhesive layer formed between the heat dissipation layer and the second semiconductor device.

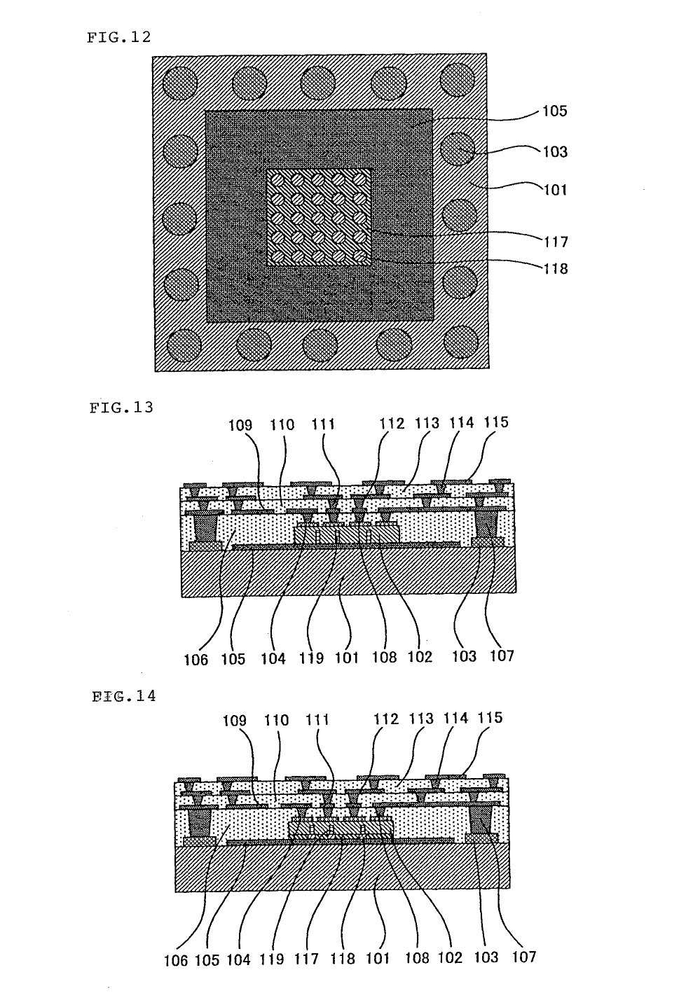

As described above, an adhesive layer may be provided between the heat dissipation layer and the second semiconductor device. However, in order to improve the thermal conductivity of the adhesive layer, as shown in FIGS. 11 and 12, heat dissipation passages can also be provided in the adhesive layer. FIG. 11 is a schematic sectional view for describing the exemplary embodiment. FIG. 12 is a top view showing a state in which heat dissipation layer 105 is formed on second semiconductor device 101, and in which adhesive layer 117 having heat dissipation passages 118 therein is formed on heat dissipation layer 105. As shown in FIG. 11, each heat dissipation passage 118 is formed in adhesive layer 117 so as to penetrate adhesive layer 117. The upper end of heat dissipation passage 118 is in contact with second semiconductor device 102, and the lower end of heat dissipation passage 118 is in contact with heat dissipation layer 105. With such configuration, the heat generated in second semiconductor device 102 can be efficiently dissipated by heat dissipation layer 105.

The heat dissipation passage can be formed, for example, in such a manner that an opening is formed in the adhesive layer, and then the above-described heat dissipation material is filled in the opening. The heat dissipation passage may be provided after the adhesive layer is formed on the heat dissipation layer or may be provided beforehand in the adhesive layer itself.

The shape of the heat dissipation passage is not limited in particular, and for example, the horizontal sectional shape of the heat dissipation passage can be formed into a circular shape or a polygonal shape, such as a rectangular shape. Further, the diameter of the heat dissipation passage is not limited in particular, and can be set to, for example, about 5 to 300 μm.

A plurality of the heat dissipation passages can be formed, but the plurality of heat dissipation passages are not limited to have the same shape. The plurality of heat dissipation passages may have different shapes.

### Exemplary Embodiment 5

The exemplary embodiment describes an embodiment where a heat dissipation path is provided in the second semiconductor device.

FIG. 13 is a schematic sectional view for describing the exemplary embodiment in which second heat dissipation path 119 is formed in second semiconductor device 102. Second heat dissipation path 119 is made of a material having thermal conductivity higher than the thermal conductivity of the material of the second semiconductor device. Further, the lower end of second heat dissipation path 119 is located on the surface of second semiconductor device 102, which surface is opposite to the circuit surface of second semiconductor device 102. Further, second heat dissipation path 119 is formed in the second semiconductor device so as not to penetrate the second semiconductor device. When the second heat dissipation path is formed in the second semiconductor device, the heat generated by the electronic circuit of the second semiconductor device can be effectively dissipated to the heat dissipation layer.

The method for forming the second heat dissipation path is not limited in particular, and the second heat dissipation path can be formed, for example, in such a manner that an opening portion is formed by a D-RIE (Deep-Reactive Ion Etching) method or a laser method, and then the above-described heat dissipation material is deposited in the opening portion. Examples of the method for arranging the heat dissipation material in the opening portion include, for example, a metal melting method, an electrolytic plating method, an electroless plating method, a sputtering method, a vapor deposition method, and the like.

The position at which the second heat dissipation path is provided is not limited in particular, but it is preferred that the circuit surface side end (the upper end in FIG. 11) of the second heat dissipation path is provided in the vicinity of a hot spot at which power consumption is concentrated in the second semiconductor device. Examples of the hot spot include a logic circuit block, a CPU block, and the like. Therefore, it is preferred that the circuit surface side end of the second heat dissipation path is located below the logic circuit block or the CPU block of the second semiconductor device.

Further, the second heat dissipation path can be formed in consideration of the arrangement of the electronic circuit and the like, in the second semiconductor device. A plurality of the second heat dissipation paths can be formed in the second semiconductor device in a point-symmetrical manner or in a line-symmetrical manner in plan view.

The shape of the second heat dissipation path is not limited in particular, and for example, the horizontal sectional shape of the second heat dissipation path can be formed into a circular shape or a polygonal shape, such as a rectangular shape. Further, the diameter of the second heat dissipation path is not limited in particular, and can be set to, for example, about 5 to 50 μm. The second heat dissipation path may be formed beforehand in the substrate of the semiconductor device or may be formed after the semiconductor device is formed.

A plurality of the second heat dissipation paths can be formed in the second semiconductor device, but are not limited to have the same shape. The plurality of second heat dissipation paths may have different shapes.

Further, in the case where the adhesive layer having the heat dissipation passage is provided between the heat dissipation layer and the second semiconductor device, it is preferred that each of heat dissipation passage 118 and each second heat dissipation path 119 is formed so as to be in contact with each other as shown in FIG. 14. That is, it is preferred that heat dissipation passage 118 is formed to penetrate adhesive layer 117 and is provided so as to be in contact with second heat dissipation path 119 and heat dissipation layer 105.

### Exemplary Embodiment 6

The exemplary embodiment describes an embodiment where a heat dissipation path is formed in the first semiconductor device.

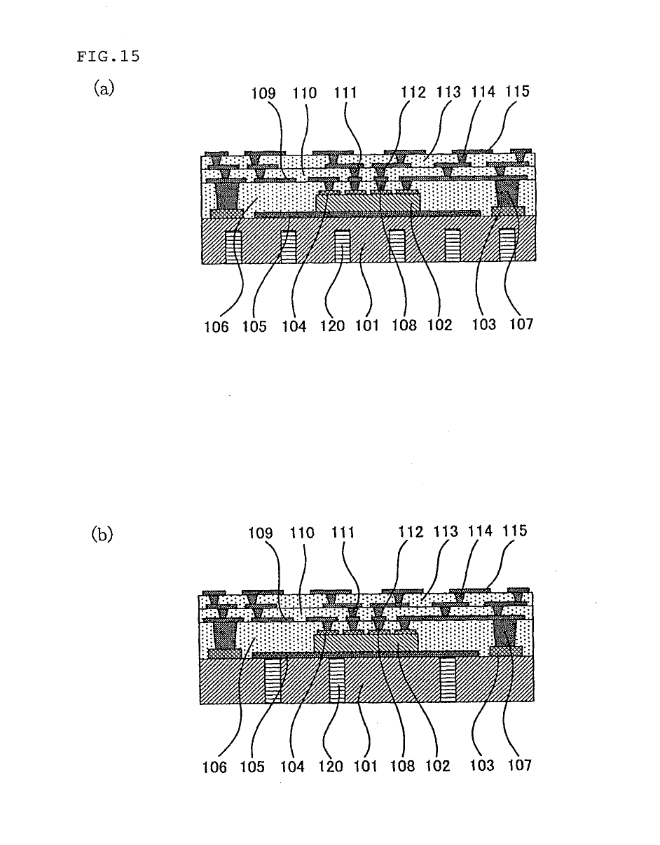

FIG. 15 is a schematic sectional view for describing the exemplary embodiment in which first heat dissipation path 120 is formed in first semiconductor device 101. First heat dissipation path 120 is made of a material having thermal conductivity higher than the thermal conductivity of the material of the first semiconductor device. Further, the lower end of first heat dissipation path 120 is located on the surface of first semiconductor device 101, which surface is opposite to the circuit surface of first semiconductor device 101, and is exposed to an outside.

First heat dissipation path 120 may be formed in first semiconductor device 101 so as not to penetrate first semiconductor device 101 as shown in FIG. 15(a). Further, as shown in FIG. 15(b), first heat dissipation path 120 can also be formed to penetrate first semiconductor device 101 so that the upper end of first heat dissipation path 120 is in contact with heat dissipation layer 105. When first heat dissipation path 120 is configured so as to be in contact with heat dissipation layer 105, it is possible to efficiently dissipate the heat of heat dissipation layer 105 to the outside.

The first heat dissipation path can be formed by the same method as the method for forming the second heat dissipation path.

The position at which the first heat dissipation path is provided is not limited in particular, but it is preferred that, in the case where the first heat dissipation path is formed so as not to penetrate the first semiconductor device, the circuit surface side end (the upper end in FIG. 15(b)) of the first heat dissipation path be provided in the vicinity of a hot spot at which power consumption is concentrated in the first semiconductor device. Examples of the hot spot include a logic circuit block, a CPU block, and the like. In the case where the first heat dissipation path is formed so as to penetrate the first semiconductor device, the first heat dissipation path is formed in consideration of the position thereof so as to prevent the function of the first semiconductor device from being destroyed. For example, the first heat dissipation path can be provided in the area in which the function blocks of the first semiconductor device are not provided.

Further, the first heat dissipation path can be formed in consideration of the arrangement of the electronic circuit, and the like, of the first semiconductor device. A plurality of the first heat dissipation paths can be formed in the second semiconductor device in a point-symmetrical manner or in a line-symmetrical manner in plan view.

The shape of the first heat dissipation path is not limited in particular, and for example, the horizontal sectional shape of the first heat dissipation path can be formed into a circular shape or a polygonal shape, such as a rectangular shape. Further, the diameter of the first heat dissipation path is not limited in particular, and can be set to, for example, about 5 to 50 μm. The first heat dissipation path may be formed beforehand in the substrate of the semiconductor device or may be formed after the semiconductor device is formed.

A plurality of the first heat dissipation paths can be formed in the first semiconductor device, but are not limited to have the same shape. The plurality of first heat dissipation paths may have different shapes.

Further, when it is configured such that a heat sink is provided on the back surface of the first semiconductor device so as to be in contact with the first heat dissipation path, it is possible to more efficiently dissipate the heat to the outside via the first heat dissipation path.

### Exemplary Embodiment 7

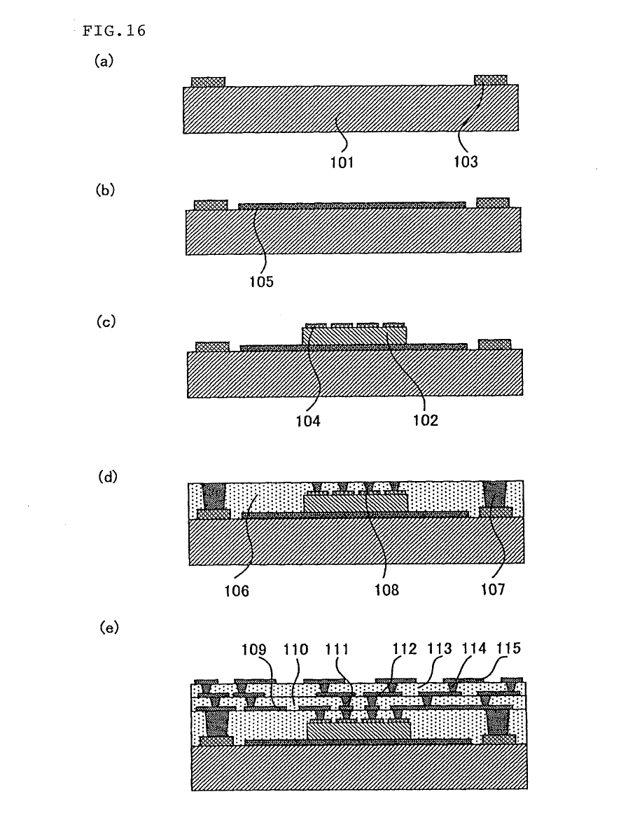

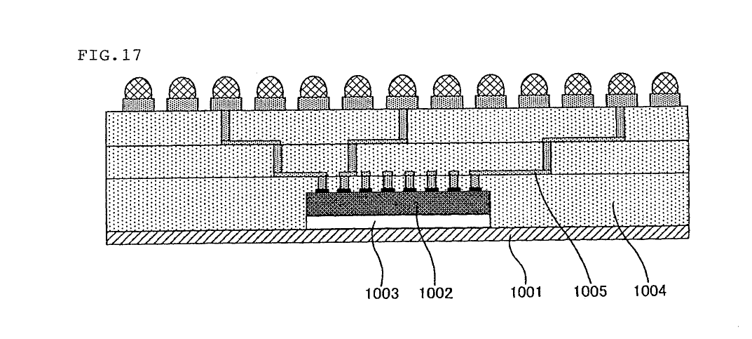

FIG. 16(a) to FIG. 16(e) are cross-sectional process diagrams for describing a manufacturing method of the substrate with the built-in semiconductor device of the exemplary embodiment shown in FIG. 1.

First, as shown in FIG. 16(a), first semiconductor device 101 having first electrode terminals 103 is prepared.

First semiconductor device 101 can be formed by a semiconductor process, and for the purpose of manufacture with high yield, it is desired that first semiconductor device 101 have a wafer form.

Next, as shown in FIG. 16(b), heat dissipation layer 105 made of a heat dissipation material is formed on the circuit surface side of first semiconductor device 101.

The forming method of the heat dissipation layer can be selected in consideration of the heat dissipation material, and it is possible to use, for example, an electrolytic plating method, an electroless plating method, a transfer molding method, a compressed formation molding method, a printing method, a vacuum press method, a vacuum lamination method, a spin coating method, a die coating method, a curtain coating method, or the like.

Next, as shown in FIG. 16(c), second semiconductor device 102 having second electrode terminals 104 is mounted on heat dissipation layer 105 so that second electrode terminals 104 are located on the upper side.

At this time, second semiconductor device 102 may be mounted on heat dissipation layer by using an adhesive layer.

Next, as shown in FIG. 16(d), insulating layer 106 is formed so as to incorporate therein second semiconductor device 102. Further, wiring connected via 107 connected to first electrode terminal 103, and device connected via 108 connected to second electrode terminal 104 are formed in insulating layer 106.

As the forming method of insulating layer 106, it is possible to use, for example, a transfer molding method, a compressed formation molding method, a printing method, a vacuum press method, a vacuum lamination method, a spin coating method, a die coating method, a curtain coating method, or the like.

For example, in the case where insulating layer 106 is made of a photosensitive material, the opening of wiring connected via 107 can be formed by using a photolithography method. Further, in the case where insulating layer 106 is formed of a non-photosensitive material or a photosensitive material with a low pattern resolution, the via opening can be formed by a laser processing method, a dry etching method, or a blasting method. As the method for filling a conductor into the via opening, it is possible to use, for example, an electrolytic plating method, an electroless plating method, a printing method, a molten metal suction method, or the like.

Note that device connected via 108 and wiring connected via 107 may also be formed in such a manner that metallic posts are respectively provided on first electrode terminal 103 and second electrode terminal 104 before the formation of insulating layer 106, and that, after insulating layer 106 is laminated, each of the metallic posts is exposed by grinding the surface of insulating layer 106. Examples of the grinding method include a buff polishing method, a CMP method, and the like.

Next, as shown in FIG. 16(e), wiring layers, such as first wiring layer 109, second wiring layer 112, and third wiring layer 115, are formed.

The wiring layers can be formed, for example, by a subtractive method, a semi-additive method, a full additive method, or the like, by using a metal such as, for example, Cu, Ni, Sn, or Au.

The subtractive method is disclosed, for example, in JP10-51105A. The subtractive method is a method in which a desired wiring pattern is obtained in such a manner that a copper foil provided on a substrate or resin is etched by using, as an etching mask, a resist formed in a desired pattern, and after the etching, the resist is removed. The semi-additive method is disclosed, for example, in JP9-64493A. The semi-additive method is a method in which a desired wiring pattern is obtained in such a manner that after a feeding layer is formed, a resist is formed in a desired pattern, and that a metal is deposited in the opening portion of the resist by electrolytic plating, and then the feeding layer is etched after removing the resist. The feeding layer can be formed, for example, by an electroless plating method, a sputtering method, a CVD method, or the like. The full additive method is disclosed, for example, in JP6-334334A. In the full additive method, first, after an electroless plating catalyst is made to adhere to the surface of a substrate or the surface of resin, a pattern is formed by a resist. Then, a desired wiring pattern is obtained in such a manner that the catalyst is activated in the state where the resist is left as an insulating layer, and that a metal is deposited in the opening portion of the insulating layer by an electroless plating method.

As the forming method of the wiring insulating layer, it is possible to use a transfer molding method, a compressed formation molding method, a printing method, a vacuum press method, a vacuum lamination method, a spin coating method, a die coating method, a curtain coating method, or the like.

Further, although not illustrated, it is also possible to provide external connection terminals on the outermost layer. The external connection terminals may also be used as a signal wiring and a ground wiring. In this case, the external connection terminals can be formed by etching a solder resist so that a part of the signal wiring and of the ground wiring is exposed.

This application claims the benefit of priority from Japanese Patent Application No. 2010-081443 filed in Japan on Mar. 31, 2010, the entire content of which is hereby incorporated by reference in the application and claims of the present application.

In the above, the present invention is described with reference to the exemplary embodiments, but the present invention is not limited to the above described exemplary embodiments. A configuration and details of the present invention may be modified in various ways within the scope of the present invention in a manner that a person skilled in the art can understand.

### REFERENCE SIGNS LIST

101 First semiconductor device
102 Second semiconductor device
103 First electrode terminal
104 Second electrode terminal
105 Heat dissipation layer
105a Heat dissipation plane
105b Heat dissipation pathway
106 Insulating layer
107 Wiring connected via
108 device connected via
109 First wiring layer
110 First wiring insulating layer
111 First wiring via
112 Second wiring layer
113 Second wiring insulating layer
114 Second wiring via
115 Third wiring layer
116 Heat dissipation via
117 Adhesive layer
118 Heat dissipation passage
119 Second heat dissipation path
120 First heat dissipation path

What is claimed is:

1. A semiconductor device built-in substrate comprising:
a first semiconductor device serving as a substrate;
a second semiconductor device placed on a circuit surface side of the first semiconductor device in a state where the circuit surfaces of the first and second semiconductor devices are placed to face in a same direction; and
an insulating layer in which the second semiconductor device is embedded, and
wherein a heat dissipation layer is formed at least between the first semiconductor device and the second semiconductor device, and
the heat dissipation layer is formed on the first semiconductor device so as to extend to an outer side of the second semiconductor device.

2. The semiconductor device built-in substrate according to claim 1, wherein the heat dissipation layer is formed to cover at least a whole surface of the second semiconductor device, the surface being opposite to the circuit surface of the second semiconductor device.

3. The semiconductor device built-in substrate according to claim 1, wherein at least a part of the heat dissipation layer is exposed to an outside.

4. The semiconductor device built-in substrate according to claim 1, wherein the heat dissipation layer is formed in an area in which the second semiconductor device is placed and in an area which does not face each function block of the first semiconductor device.

5. The semiconductor device built-in substrate according to claim 1, wherein the heat dissipation layer includes a heat dissipation plane on which the second semiconductor device is placed, and a heat dissipation pathway extended from the heat dissipation plane, and
the heat dissipation pathway is formed between the respective function blocks of the first semiconductor device.

6. The semiconductor device built-in substrate according to claim 5, wherein an end portion of the heat dissipation pathway is exposed to an outside.

7. The semiconductor device built-in substrate according to claim 1, wherein the heat dissipation layer is formed of a material having thermal conductivity higher than thermal conductivity of the first semiconductor device and the second semiconductor device.

8. The semiconductor device built-in substrate according to claim 1, further comprising
a first wiring layer facing the first semiconductor device and the second semiconductor device via the insulating layer,
wherein at least one of wirings of the first wiring layer is electrically connected to an electrode terminal of the second semiconductor device, and
at least one of wirings of the first wiring layer is electrically connected to an electrode terminal of the first semiconductor device via a wiring connected via formed in the insulating layer.

9. The semiconductor device built-in substrate according to claim 8, further comprising a heat dissipation via in the insulating layer, the heat dissipation via being in contact with the first wiring layer and the heat dissipation layer.

10. The semiconductor device built-in substrate according to claim 9, wherein the heat dissipation via is not connected to the wiring connected via by a wiring.

11. The semiconductor device built-in substrate according to claim 9, further comprising
one or more second wiring layers and an external connection terminal as an outermost layer, which are located on the side of the first wiring layer, and
a heat dissipation wiring, which is connected to the heat dissipation via, in the first wiring layer and the one or more second wiring layers,
wherein the heat dissipation wiring is connected to at least one of the external connection terminals.

12. The semiconductor device built-in substrate according to claim 1, wherein the second semiconductor device includes therein a second heat dissipation path which has an end located on a surface of the second semiconductor device, the surface being opposite to the circuit surface of the second semiconductor device, and which is made of a material having thermal conductivity higher than thermal conductivity of the material of the second semiconductor device.

13. The semiconductor device built-in substrate according to claim 12, wherein an end of the second heat dissipation path, the end being opposite to the end located on the surface opposite to the circuit surface of the second semiconductor device, is located at a logic circuit block or a CPU block in the second semiconductor device.

14. The semiconductor device built-in substrate according to claim 1, further comprising an adhesive layer between the second semiconductor device and the heat dissipation layer.

15. The semiconductor device built-in substrate according to claim 14, wherein the adhesive layer includes a heat dissipation passage in contact with the second semiconductor device and the heat dissipation layer.

16. The semiconductor device built-in substrate according to claim 12, further comprising
an adhesive layer including a heat dissipation passage between the second semiconductor device and the heat dissipation layer,
wherein the heat dissipation passage is formed to penetrate the adhesive layer so as to contact the second heat dissipation path and the heat dissipation layer.

17. The semiconductor device built-in substrate according to claim 1, wherein the first semiconductor device includes therein a first heat dissipation path which has an end located on a surface of the first semiconductor device, the surface being opposite to the circuit surface of the first semiconductor device, and which is made of a material having thermal conductivity higher than thermal conductivity of the material of the first semiconductor device.

18. The semiconductor device built-in substrate according to claim 17, wherein the first heat dissipation path is provided to penetrate the first semiconductor device, and an end of the first heat dissipation path, the end being opposite to the end located on the surface opposite to the circuit surface of the first semiconductor device, is in contact with the heat dissipation layer.

19. The semiconductor device built-in substrate according to claim 17, wherein a heat sink is provided on the surface side of the first semiconductor device, the surface side being opposite to the circuit surface of the first semiconductor device, and the first heat dissipation path is connected to the heat sink.
